(19) United States
(12) Patent Application Publication
(10) Pub. No.: US 2024/0222438 A1
(43) Pub. Date: Jul. 4, 2024

(54) TRANSISTOR INCLUDING WIDE BAND GAP MATERIALS

(71) Applicant: Intel Corporation, Santa Clara, CA (US)

(72) Inventors: Abhishek Anil SHARMA, Portland, OR (US); Han Wui THEN, Portland, OR (US); Tahir GHANI, Portland, OR (US); Anand S. MURTHY, Portland, OR (US); Wilfred GOMES, Portland, OR (US); Sagar SUTHRAM, Portland, OR (US); Pushkar RANADE, San Jose, CA (US)

(21) Appl. No.: 18/089,945

(22) Filed: Dec. 28, 2022

(51) Int. Cl. H01L 29/26; H01L 29/36; H01L 29/40; H01L 29/423; H01L 29/66; H01L 29/778

(52) U.S. Cl. CPC H01L 29/26; H01L 29/36; H01L 29/401; H01L 29/4236; H01L 29/42368; H01L 29/66462; H01L 29/7787

(57) ABSTRACT

Embodiments described herein may be related to apparatuses, processes, systems, and/or techniques for designing and fabricating semiconductor packages that include transistors that include wide band gap materials, such as silicon carbide or gallium nitride. Other embodiments may be described and/or claimed.

### FIELD

Embodiments of the present disclosure generally relate to the field of semiconductor manufacturing, and in particular to packages that include transistors.

### BACKGROUND

Continued growth in virtual machines, cloud computing, and portable devices will continue to increase the demand for high density transistors within chips and packages. This is particularly true with compute dies that are interacting with large amounts of memory for high bandwidth (HBW) computing, where increased amounts of power and memory may be required for operation.

### BRIEF DESCRIPTION OF THE DRAWINGS

FIGS. 1A-1B show various cross-section side views of diagrams of a semiconductor package that include a silicon carbide (SiC) layer next to a gallium nitride (GaN) layer to provide voltage conversion for the package, in accordance with various embodiments.

FIG. 2 shows an example of a legacy junction gate field effect transistor (JFET).

FIGS. 3A-3C show cross-section side views of examples of a transistor made of multiple wide band gap materials, in accordance with various embodiments.

FIG. 4 shows a cross-section side view of a transistor that includes multiple wide band gap layers, in accordance with various embodiments.

FIG. 5 illustrates a side view of a diagram of a wafer scale engine (WSE) that includes Zetta memory that is powered by high voltage input that is converted using devices within a SiC layer coupled with devices within a wide band gap layer, in accordance with various embodiments.

FIG. 6 illustrates an example process for creating a package that includes transistors that include additional layers between the transistor body and a source or drain contact, where the additional layers include SiC or GaN, in accordance with various embodiments.

FIG. 7 illustrates a computing device in accordance with one implementation of the invention.

FIG. 8 illustrates an interposer that includes one or more embodiments of the invention.

FIG. 9A illustrates a computing device in accordance with one implementation of an embodiment of the present disclosure.

FIG. 9B illustrates a processing device in accordance with one implementation of an embodiment of the present disclosure.

### DETAILED DESCRIPTION

Embodiments described herein may be related to apparatuses, processes, systems, and/or techniques for designing and fabricating semiconductor packages that include transistors that include wide band gap materials, such as SiC or GaN. In embodiments, wide band gap materials may be materials with a band gap greater than two electron volts.

In embodiments, the transistors may have a structure similar to a junction gate field effect transistor (JFET). In embodiments, there may be two source contacts at one side of the transistor, and a drain contact at the other side of the transistor, with one or more gates between the two source contacts and between the source contacts and the drain contact. In embodiments, there may be different materials, or different doping, between the first source contact and the transistor body, and the second source contact and the transistor body. As a result, where two gates are in the transistor, a first voltage applied to the first gate may be sufficient to activate the electrical path connecting to only the first source, and a second voltage applied to the second gate may be sufficient to activate the electrical path connecting to the second source.

In other embodiments, the transistors may include a gate spacer, or gate oxide, that may be charged or polarized. The charged or polarized gate spacer may be used to improve conductivity between the source contacts and the transistor body. In embodiments, transistors may include varying distances between the source contacts and the body of the transistor. For example, by increasing the distances, particularly through wide band gap materials such as SiC or GaN, the effective electrical gate length of the transistor may be increased, thus reducing leakage during transistor operation.

In embodiments, the transistors may be used as a part of a wafer scale engine (WSE) that may be used to facilitate Zetta scale memory and computing. In embodiments, the transistors described herein may be used for higher voltages to increase the overall amount of power that may be provided to operate the WSE, and to deliver a smaller current level.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

In embodiments, high-Tc conductors are utilized for global routing. Implementation of embodiments described herein can include the presence of such materials in a metal layer and/or at the package level. Implementation of embodiments described herein can include the fabrication of inductors and/or through silicon vias (TSVs) with the same. Implementation of embodiments described herein can include fabrication of a separate metal stack (bonded or monolithic) for custom routing of finished product wafers. Implementation of embodiments described herein can include the introduction of high Tc superconductors (single crystal or deposited— atomic layer deposition (ALD) and/or chemical vapor deposition (CVD) may be used to reduce the IR drop across long distances including between die stitching.

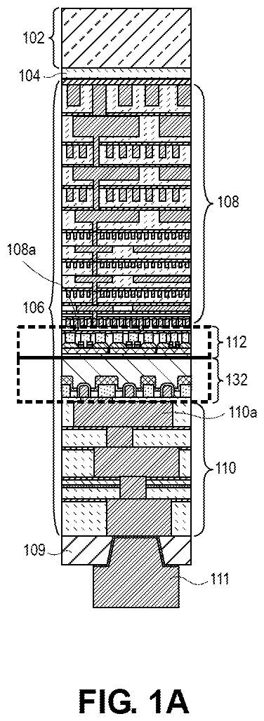

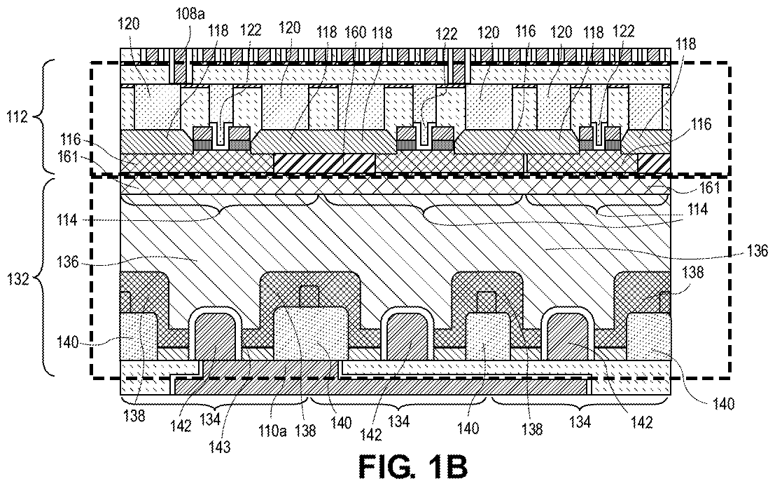

FIGS. 1A-1B show various cross-section side views of diagrams of a semiconductor package that include a silicon carbide (SiC) layer next to a gallium nitride (GaN) layer to provide voltage conversion for the package, in accordance with various embodiments. FIG. 1A shows an embodiment that is a side view of a carrier wafer 102 that is bonded to a package 106 using an adhesive 104. The package 106 may include front side routing layers 108, which may include traces and conductive vias used to route low-voltage power and/or signals, e.g. 1-1.8 V. The package 106 may also include back side routing layers 110, which may include power routings and conductive vias, that may route high-voltage power, e.g. handle voltage sources that are greater than 1 kV.

In embodiments, a GaN layer 112 may be below the front side routing layers 108 and various devices (described in FIG. 1B) within the GaN layer 112 may be electrically coupled with one or more of the routing elements within the front side routing layers 108, for example via 108a. A SiC layer 132 may be between the GaN layer 112 and the back side routing layers 110, and various devices (described in FIG. 1B) formed within the SiC layer 132 may be electrically coupled with one or more of the routing elements within the back side routing layers 110, for example high-voltage connector 110a. In embodiments, a bump 111, which may include a solder ball or a copper pad, may be electrically coupled with the back side routing layers 110 to provide high-voltage power from an outside source. In embodiments, the bump 111 may be surrounded by a dielectric 109.

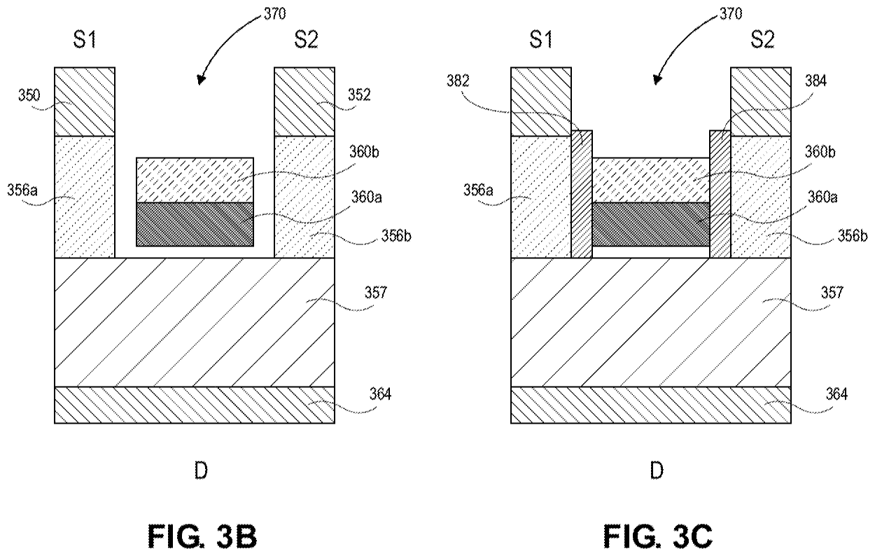

FIG. 1B illustrates an enlarged view of the GaN layer 112 and the SiC layer 132 of FIG. 1A. In embodiments, the GaN layer 112 may include a plurality of transistors 114 that are on a GaN material 116. Each of the transistors 114 may include a doped GaN region 118 onto which contacts 120 are coupled. A gate 122 may be between the various contacts 120. In embodiments, there may be via 108a between a contact 120 and the front side routing layers 108 of FIG. 1A to provide a lower voltage, for example between 1 and 1.8 V, to the front side routing layers 108. Note that in this embodiment, the transistors 114 are “face up,” with the contacts 120 and the gate 122 facing toward the front side routing layers 108 of FIG. 1A. In other embodiments, the transistors 114 may be in some other configuration or some other orientation, and in particular as described in embodiments below with respect to FIGS. 3A-3C. In embodiments, one or more back side power connectors 160, which may be Power Vias™, may electrically couple with the doped GaN region 118. In addition, there may be additional elements, such as interconnects, thru silicon vias and capacitors (not shown) within the GaN layer 112.

In embodiments, the SiC layer 132 may include a plurality of transistors 134 that are within a SiC material 136. The transistors 134 may include a doped region 138 onto which contacts 140 are coupled. A gate 142 may be formed between the contacts 140. In embodiments, the gate 142 may be a poly silicon gate that may be surrounded by another suitably doped semiconductor region 143. In embodiments, the gate 142 and/or the contacts 140 may be electrically coupled with the high-voltage connector 110a, that may be coupled with the back side routing layers 110 of FIG. 1A. Note that in this embodiment, the transistors 134 are “face down,” with contacts 140 and the gate 142 facing toward the back side routing layers 110 of FIG. 1A. In embodiments, this configuration may allow a more efficient, lower loss connection with the high-voltage connector 110a. In other embodiments, the transistors 134 may be in some other configuration or some other orientation, and in particular as described in embodiments below with respect to FIGS. 3A-3C. In addition, there may be additional elements, such as interconnects, thru silicon vias and capacitors (not shown) within the SiC layer 132. In embodiments, there may be a doped SiC region 161, which may have a N+ doping, within the SiC layer 132.

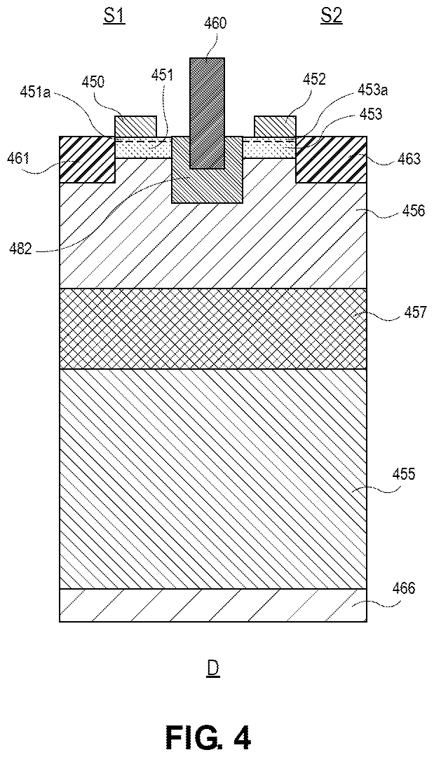

Note that the transistors shown in GaN layer 112 or SiC layer 132, in particular transistors 114 and transistors 134, may be implemented according to embodiments shown below, in particular with respect to FIGS. 3A-4.

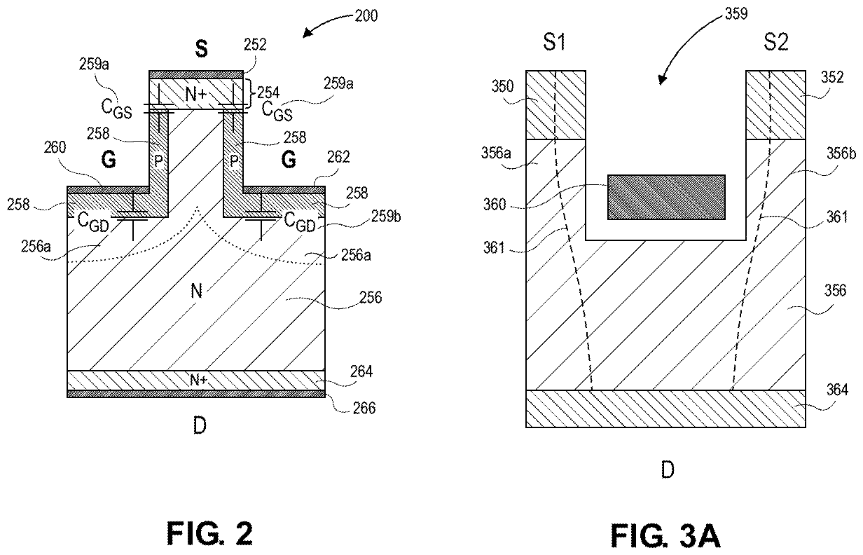

FIG. 2 shows an example of a legacy junction gate field effect transistor (JFET). Legacy transistor 200 shows a cross-section side view that includes a source contact 252 that may be on top of an epitaxial layer 254 that has an N+ doping, which in turn is on the body 256, which may have an N doping. The epitaxial layer 254 may be above regions 258 that include P doping. In embodiments, the regions 258 that include P doping may extend underneath a first gate 260 and a second gate 262.

In embodiments, there may be another suitably doped region 256a within the body 256. In embodiments, the body 256 may be on a region 264 that has N+ doping. A drain 266 may be below the region 264. As shown, there may be a capacitance C_{GS} 259a between the epitaxial layer 254 and the first gate 260 and the second gate 262, and a capacitance C_{GD} 259b between the regions 258 and the drain 266. These capacitances are parasitic and undesirable because they do not contribute to transistor operation and performance.

FIGS. 3A-3C show cross-section side views of examples of a transistor made of multiple wide band gap materials, in accordance with various embodiments. FIG. 3A shows an embodiment of a transistor that includes a drain region 364, or drain epitaxial, and a body 356 on the drain region 364. In embodiments, the body 356 may be a wide band gap material, which may include SiC or GaN. In this embodiment, the body 356 may have a first side 356a and a second side 356b in the cross-section on either side of a buried gate 360. In embodiments, the first side 356a and the second side 356b may be formed by etching a cavity 359 into the body 356. In embodiments, other techniques, such as epitaxial growth or layer transfer, may be used to produce the cavity 359.

In embodiments, the buried gate 360 may include poly silicon, a silicide material, a metal such as tungsten, titanium, or tantalum, or a metal composite such as tungsten nitride, titanium nitride, or tantalum nitride. In embodiments, the buried gate 360 may be placed using deposition techniques that are known in the art.

In embodiments, a first source epitaxial 350 may be on the first side 356a, and a second source epitaxial 352 may be on the second side 356b. In embodiments, the first source epitaxial 350 and the second source epitaxial 352 may be grown on the body 356, or may be applied using layer transfer techniques. A height of the first side 356a, the height of a second side 356b, and a height of the first source epitaxial 350 and of the second source epitaxial 352 may be selected for a specific electrical path length 361. In embodiments, these techniques may be used to increase or decrease negative XUD within the transistor of FIG. 3A.

In embodiments, the first side 356a and the second side 356b may include GaN. In embodiments, the first side 356a and the second side 356b may include SiC that is doped. In embodiments, the first side 356a and the second side 356b may include different materials. In embodiments the first side 356a and the second side 356b may be differently doped, may include different materials, or may have different band gaps. In these embodiments, during operation a smaller gate voltage may only turn the first side 356a on, resulting in current flowing between the first source epitaxial 350 and the drain region 364. In embodiments, a larger gate voltage may also turn the second side 356b on, resulting in current flowing between the second source epitaxial 352 and the drain region 364, thus resulting in a larger overall current flow.

FIG. 3B shows a transistor, which may be similar to the transistor of FIG. 3A, that includes a body 357, which may be similar to body 356 of FIG. 3A, that may be on a drain region 364, which may be referred to as a drain epitaxial. A first side 356a and a second side 356b may be on the body 357. In embodiments, the body 357 may include SiC, and the first side 356a and the second side 356b may include GaN. In embodiments, the first side 356a and the second side 356b may include SiC that is doped. In embodiments, the first side 356a and the second side 356b may include different materials.

In embodiments, the first source epitaxial 350 may be grown on the first side 356a, and the second source epitaxial 352 may be grown on the second side 356b. In embodiments, the first source epitaxial 350 and the second source epitaxial 352 may have started out as a common epitaxial layer into which cavity 370 was formed. In embodiments, the first source epitaxial 350 and the second source epitaxial 352 may have been grown on the first side 356a and the second side 356b.

In embodiments, a first buried gate 360a, which may be similar to buried gate 360 of FIG. 3B, may be formed within the cavity 370. In embodiments, a second buried gate 360b may be formed above the first buried gate 360a. The second buried gate provides additional gate control to enhance the transistor ON and OFF characteristics.

FIG. 3C shows a transistor, which may be similar to the transistor of FIG. 3B, that includes a body 357 that may be on a drain region 364, which may be referred to as a drain epitaxial. A first side 356a and a second side 356b may be on the body 357. In embodiments, the body 357 may include SiC, and the first side 356a and the second side 356b may include GaN. In embodiments, the first side 356a and the second side 356b may include SiC that is doped. In embodiments, the first side 356a and the second side 356b may include different materials. In embodiments, a first buried gate 360a may be formed within the cavity 370, and a second buried gate 360b may be formed above the first buried gate 360a.

In embodiments, a gate spacer 382 may be between the first buried gate 360a and the first side 356a, and/or may be between the second buried gate 360b and the first side 356a. A gate spacer 384 may be between the first buried gate 360a and the second side 356b, or may be between the second buried gate 360b and the second side 356b. In embodiments, the gate spacers 382, 384 may be a same gate spacer. In embodiments, the gate spacers 382, 384 may be charged and/or polarized, which may alter the operational characteristics, for example the threshold voltage, for the first side 356a or the second side 356b, for example to improve electrical conductivity between the first side 356a or the second side 356b.

FIG. 4 shows a cross-section side view of a transistor that includes multiple wide band gap layers, in accordance with various embodiments. FIG. 4 shows a transistor that includes a bottom electrical drain contact 466. A substrate 455, which may include a wide band gap material such as SiC, may be on the bottom electrical drain contact 466. In embodiments, the substrate 455 may have an n+ doping. In embodiments, an SiC n− drift layer 457 may be above the substrate 455. In embodiments, the SiC n− drift layer 457 may have an n− doping, and may be formed from any wide band gap material. In embodiments, a GaN n− drift layer 456 may be on the SiC n− drift layer 457. In embodiments, the GaN n− drift layer 456 may include any wide band gap material.

In embodiments, a gate 460 may be formed at a top of the GaN n− drift layer 456, and may be surrounded by a gate oxide 482. In embodiments, the gate 460 and the gate oxide 482 may extend into the GaN n− drift layer 456. At the top of the GaN n− drift layer 456, a first region 451 may be on the GaN n− drift layer 456 on a first side of the gate 460, and a second region 453 may be on the GaN n− drift layer 456 on a second side of the gate 460 opposite the first side. In embodiments, the first region 451 and the second region 453 may include undoped GaN, or p− doped GaN. In embodiments, the first region 451 may include a 2D electron gas (2DEG) 451a and the second region 453 may include a 2DEG 453a. Both the first region 451 and the second region 453 may form a quantum well within the GaN n− drift layer 456.

In embodiments, a first source epitaxial 450 may be formed on at least a portion of a surface of the first region 451, and a second source epitaxial 452 may be formed on at least a portion of a surface of the second region 453. In embodiments, the first region 451 may be between a first isolation oxide 461 and the gate oxide 482, and the second region 453 may be between a second isolation oxide 463 and the gate oxide 482. The isolation oxide 463 may be a low-k insulating dielectric, e.g., SiO₂, whereas the gate oxide 482 can be a low-k dielectric such as SiO₂, SiN and Al₂O₃, or preferably a high-k dielectric such as HfO₂, ZrO₂, etc, or a combination of such low-k and high-k dielectrics.

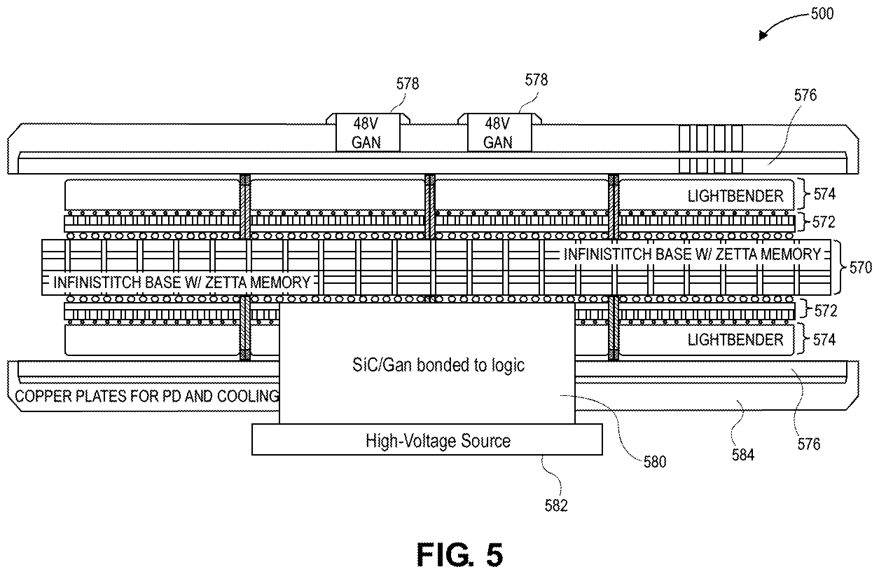

FIG. 5 illustrates a side view of a diagram of a wafer scale engine (WSE) that includes Zetta memory that is powered by high voltage input that is converted using devices within a SiC layer coupled with devices within a wide band gap layer, in accordance with various embodiments.

Embodiments described herein may be used to enable Zetta scale computing. Zetta scale computing may include an extremely large number of computing devices within a package. For example, the computing devices together may provide on the order of 1021 floating-point operations per second (FLOPS). In addition, Zetta scale computing may also involve digital storage in the form of memory, for example DRAM memory as described herein, on the order of a zettabyte, or 1021 bytes within the package. The large number of computing devices and memory devices within a package may be implemented as a WSE, which may involve an entire wafer or large portions of a wafer, or multiple wafers coupled with each other, that include repeating patterns of compute circuitry on the wafers. This may be done rather than fabricating independent dies that are subsequently stitched together.

One characteristic of a WSE is that it may include components that are tens of millimeters apart. Electrically coupling such components may involve a significant IR drop. In order to mitigate this IR drop, high voltages, for example on the order of 1 kV, may be used to route power from one area of the wafer to another, which may then be converted to 1-1.8V. In addition, a high-voltage supply may be used to provide significantly more power to a package. For example, a die on a wafer may consume on the order of 100 W, thus, if there are 200 dies on a full wafer, that will requires 20 kW to power the entire wafer. And, if it is part of a WSE that may include multiple wafers bonded with each other, this power consumption will increase with each added wafer.

WSE 500 is an embodiment that includes a plurality of layers that may include a Zetta memory 570, which may include one or more wafers that may be coupled together, where each wafer includes a plurality of memory cells, such as the DRAM cells described in embodiments herein with respect to FIGS. 1-2, and transistors described in embodiments herein with respect to FIGS. 3A-3C.

In embodiments, interconnect layers 572 may be on the top and the bottom of the Zetta memory 570, and input/output (I/O) layers 574 may be coupled, respectively, with the interconnect layers 572. In embodiments, the I/O layers 574 may include photonics circuitry (not shown). In embodiments, a heat sink 576 may be thermally coupled with the I/O layers 574 and/or the Zetta memory 570. In embodiments, a casing 584 may at least partially surround the Zetta memory 570, the interconnect layers 572, the I/O layers 574, and/or the heat sink 576.

In embodiments, power supplies 578, which may be electrically coupled with voltage source of less than 1 kV, may include devices within a GaN layer, which may be used to step the high voltage source down to 1-1.8 V for use by the Zetta memory 570. In embodiments, a converter 580, which may include transistors within a GaN layer and transistors within a SiC layer that are coupled with each other to step down a voltage that may be greater than 1 kV from a high voltage source 582, down to 1-1.8 V, for use by the Zetta memory 570.

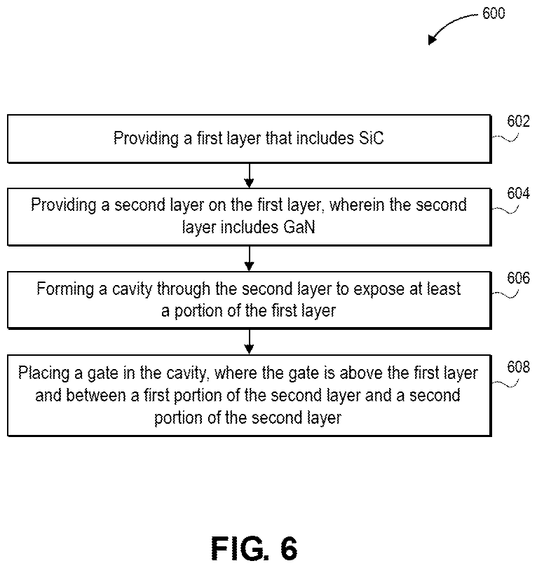

FIG. 6 illustrates an example process for creating a package that includes transistors that include additional layers between the transistor body and a source or drain contact, where the additional layers include SiC or GaN, in accordance with various embodiments. The process 600 may be performed using the processes, apparatus, systems, and/or techniques described herein, and in particular with respect to FIGS. 1A-5.

At block 602, the process may include providing a first layer that includes silicon carbide (SiC).

At block 604, the process may further include providing a second layer on the first layer, wherein the second layer includes gallium nitride (GaN).

At block 606, the process may further include forming a cavity through the second layer to expose at least a portion of the first layer.

At block 608, the process may further include placing a gate in the cavity, wherein the gate is above the first layer and between a first portion of the second layer and a second portion of the second layer.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around-gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

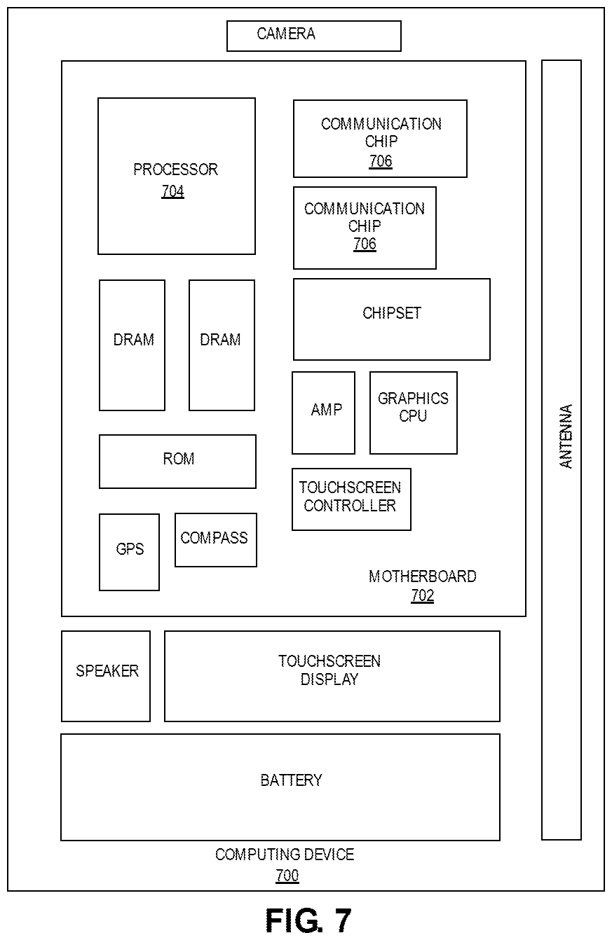

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

Depending on its applications, computing device 700 may include other components that may or may not be physically and electrically coupled to the board 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip includes one or more devices, such as MOS-FET transistors built in accordance with implementations of the invention.

In further implementations, another component housed within the computing device 700 may contain an integrated circuit die that includes one or more devices, such as MOS-FET transistors built in accordance with implementations of the invention.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

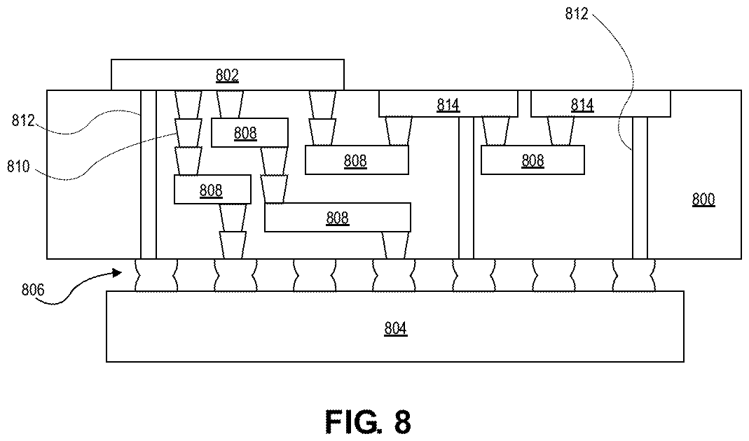

FIG. 8 illustrates an interposer 800 that includes one or more embodiments of the invention. The interposer 800 is an intervening substrate used to bridge a first substrate 802 to a second substrate 804. The first substrate 802 may be, for instance, an integrated circuit die. The second substrate 804 may be, for instance, a memory module, a computer motherboard, or another integrated circuit die. Generally, the purpose of an interposer 800 is to spread a connection to a wider pitch or to reroute a connection to a different connection. For example, an interposer 800 may couple an integrated circuit die to a ball grid array (BGA) 806 that can subsequently be coupled to the second substrate 804. In some embodiments, the first and second substrates 802/804 are attached to opposing sides of the interposer 800. In other embodiments, the first and second substrates 802/804 are attached to the same side of the interposer 800. And in further embodiments, three or more substrates are interconnected by way of the interposer 800.

The interposer 800 may be formed of an epoxy resin, a fiberglass-reinforced epoxy resin, a ceramic material, or a polymer material such as polyimide. In further implementations, the interposer 800 may be formed of alternate rigid or flexible materials that may include the same materials described above for use in a semiconductor substrate, such as silicon, germanium, and other group III-V and group IV materials.

The interposer 800 may include metal interconnects 808 and vias 810, including but not limited to through-silicon vias (TSVs) 812. The interposer 800 may further include embedded devices 814, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 800. In accordance with embodiments of the invention, apparatuses or processes disclosed herein may be used in the fabrication of interposer 800.

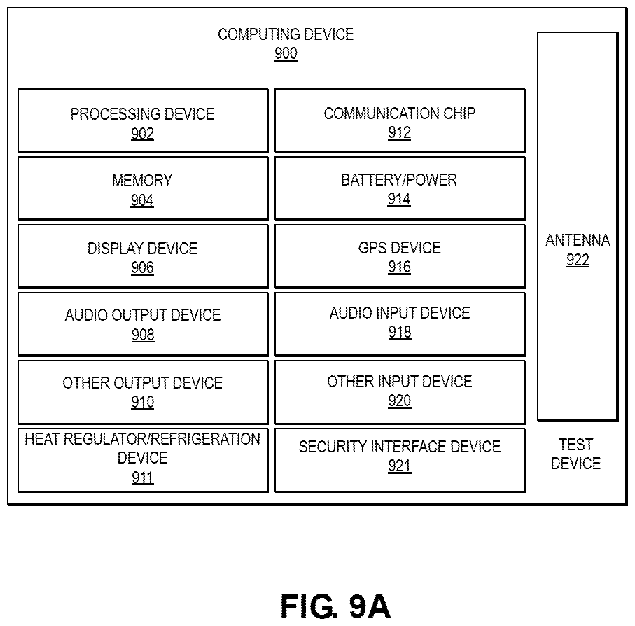

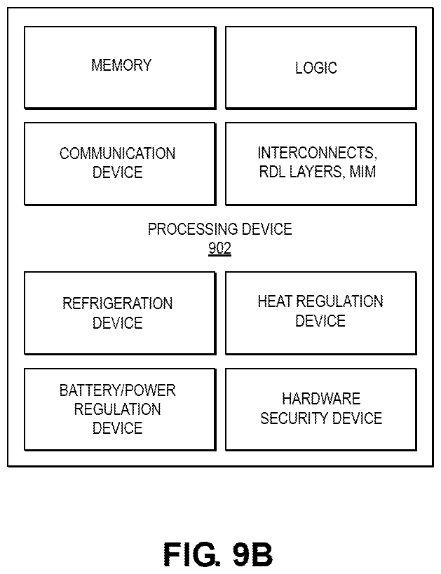

It is to be appreciated that structures described herein may be operated at a low temperature, e.g., in a range of −77 degrees Celsius to 0 degrees Celsius. In one embodiment, a heat regulator/refrigeration device is coupled to a common board having a device with structures such as those described herein coupled thereto, such as described below in association with FIG. 9A. In one embodiment, a heat regulator device and/or refrigeration device is included on a processing device having structures such as those described herein, such as described below in association with FIG. 9B.

FIG. 9A illustrates a computing device 900 in accordance with one implementation of an embodiment of the present disclosure. The computing device 900 houses a board. The board may include a number of components, including but not limited to a processing device 902. The computing device 900 can also include communication chip 912. In one embodiment, the processing device 902 is physically and electrically coupled to the board. In some implementations the communication chip 912 is also physically and electrically coupled to the board. In further implementations, the communication chip 912 is part of the processing device 902.

Depending on its applications, computing device 900 may include other components that may or may not be physically and electrically coupled to the board. These other components can include, but are not limited to, memory 904, such as volatile memory (e.g., DRAM), non-volatile memory (e.g., ROM), or flash memory, an antenna 922, a display device 906, a battery/power 914, an audio output device 908, an audio input device 918, a global positioning system (GPS) device 916, another output device 910 (such as video output), and other input device 920 (such as video input), a security interface device 921, and/or a test device. In one embodiment, a heat regulation/refrigeration device 911 is included and is coupled to the board, e.g., a device including actively cooled copper channels.

The communication chip 912 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 912 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 912. For instance, a first communication chip 912 may be dedicated to shorter range wireless communications such as Wi-Fi and Bluetooth and a second communication chip 912 may be dedicated to longer range wireless communications such as GPS, EDGE, GPRS, CDMA, WiMAX, LTE, Ev-DO, and others.

The processing device 902 of the computing device 900 can include an integrated circuit die in a package. The processing device 902 may include one or more structures, such as gate-all-around integrated circuit structures having ultra-high conductivity global routing, built in accordance with implementations of embodiments of the present disclosure. The term “processing device” may refer to any device or portion of a device that processes electronic data from registers and/or memory to transform that electronic data into other electronic data that may be stored in registers and/or memory.

FIG. 9B illustrates a processing device in accordance with one implementation of an embodiment of the present disclosure. Referring to FIG. 9B, an exemplary processing device 902 includes a memory region, a logic region, a communication device region, an interconnects and redistribution layer (RDL) and metal-insulator-metal (MIM) region, a refrigeration device region, a heat regulation device region, a batter/power regulation device region and a hardware security device region. In one embodiment, the refrigeration device region and/or the heat regulation device region is a region including actively cooled copper channels.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The following paragraphs describe examples of various embodiments.

### EXAMPLES

Example 1 is a transistor comprising: a body; a first gate on the body; a second gate on the first gate; a first material on the body, wherein the first material is at a first side of the first gate; a second material on the body, wherein the second material is at a second side of the first gate opposite the first side of the gate; and wherein the body includes a first wide band gap material, and wherein the first material or the second material is a second wide band gap material.

Example 2 includes the transistor of example 1, wherein the first gate and the second gate include different materials.

Example 3 includes the transistor of examples 1 or 2, wherein the first material has a first level of doping concentration and wherein the second material has a second level of doping concentration.

Example 4 includes the transistor of examples 1, 2, or 3, further comprising: a first electrical contact on the first material; and a second electrical contact on the second material.

Example 5 includes the transistor of example 4, wherein the first gate, the second gate, the first material, and the second material are on a first side of the body; and further comprising a third electrical contact on the second side of the body opposite the first side of the body.

Example 6 includes the transistor of example 5, wherein the first electrical contact is a first source contact, wherein the second electrical contact is a second source contact, and wherein the third electrical contact is a drain contact.

Example 7 includes the transistor of examples 1, 2, 3, 4, 5, or 6, further comprising: a first oxide layer between the first material and the first side of the first gate; and a second oxide layer between the second material and the second side of the first gate.

Example 8 includes the transistor of example 7, wherein the first oxide layer or the second oxide layer is a selected one or more of: an active oxide layer or a polarized oxide layer.

Example 9 includes the transistor of examples 7 or 8, wherein the first oxide layer and the second oxide layer are a same oxide layer.

Example 10 includes the transistor of examples 1, 2, 3, 4, 5, 6, 7, 8, or 9, wherein the first wide band gap material includes silicon carbide, and wherein the second wide band gap material includes gallium nitride.

Example 11 includes the transistor of examples 1, 2, 3, 4, 5, 6, 7, 8, 9, or 10, wherein the transistor is a part of a wafer scale engine (WSE).

Example 12 is a transistor comprising: a first layer that includes silicon carbide (SiC); a second layer on the first layer, the second layer includes gallium nitride (GaN); a gate oxide on a portion of the second layer; and a gate on the gate oxide.

Example 13 is includes the transistor of example 12, wherein the gate oxide extends into the second layer.

Example 14 includes the transistor of examples 12 or 13, further comprising: a first isolation oxide on the second layer; a second isolation oxide on the second layer, wherein the gate oxide is between the first isolation oxide at the second isolation oxide; and wherein the first isolation oxide and the second isolation oxide extend into the second layer.

Example 15 includes the transistor of example 14, further comprising: a first region within the second layer and proximate to a top of the second layer, wherein the first region is between the gate oxide and the first isolation oxide; and a second region within the second layer and proximate to a top of the second layer, wherein the second region is between the gate oxide and the second isolation oxide.

Example 16 includes the transistor of example 15, wherein the first region or the second region includes GaN that is p-doped.

Example 17 includes the transistor of examples 15 or 16, wherein the first region or the second region includes a 2D electron gas (2DEG).

Example 18 includes the transistor of examples 15, 16, or 17, further comprising: a first epitaxial on the first region, wherein the first epitaxial has an n+ doping; and a second epitaxial on the second region, wherein the second epitaxial has a n+ doping.

Example 19 includes the transistor of examples 12, 13, 14, 15, 16, 17, or 18, further comprising a third layer below the first layer, wherein the third layer includes SiC, wherein the third layer includes n+ doping, and wherein the first layer includes n− doping.

Example 20 includes the transistor of example 19, wherein the first layer includes n− doping.

Example 21 includes the transistor of examples 12, 13, 14, 15, 16, 17, 18, 19, or 20, further comprising an electrical contact below the first layer.

Example 22 is a method comprising: providing a first layer that includes silicon carbide (SiC); providing a second layer on the first layer, wherein the second layer includes gallium nitride (GaN); forming a cavity through the second layer to expose at least a portion of the first layer; and placing a gate in the cavity, wherein the gate is above the first layer and between a first portion of the second layer and a second portion of the second layer.

Example 23 includes the method of example 22, wherein the first portion of the second layer has a different doping than the second portion of the second layer.

Example 24 includes the method of examples 22 or 23, further comprising: forming a first oxide layer between the first portion of the second layer and the gate; and forming a second oxide layer between the second portion of the second layer in the gate, wherein the first oxide layer or the second oxide layer is a selected one or more of: an active oxide layer or a polarized oxide layer.

Example 25 includes the method of examples 22, 23, or 24, further comprising placing an electrical contact below the first layer.

What is claimed is:

1. A transistor comprising:
a body;
a first gate on the body;
a second gate on the first gate;
a first material on the body, wherein the first material is at a first side of the first gate;
a second material on the body, wherein the second material is at a second side of the first gate opposite the first side of the gate; and
wherein the body includes a first wide band gap material, and wherein the first material or the second material is a second wide band gap material.

2. The transistor of claim 1, wherein the first gate and the second gate include different materials.

3. The transistor of claim 1, wherein the first material has a first level of doping concentration and wherein the second material has a second level of doping concentration.

4. The transistor of claim 1, further comprising:
a first electrical contact on the first material; and
a second electrical contact on the second material.

5. The transistor of claim 4, wherein the first gate, the second gate, the first material, and the second material are on a first side of the body; and further comprising a third electrical contact on the second side of the body opposite the first side of the body.

6. The transistor of claim 5, wherein the first electrical contact is a first source contact, wherein the second electrical contact is a second source contact, and wherein the third electrical contact is a drain contact.

7. The transistor of claim 1, further comprising:
a first oxide layer between the first material and the first side of the first gate; and
a second oxide layer between the second material and the second side of the first gate.

8. The transistor of claim 7, wherein the first oxide layer or the second oxide layer is a selected one or more of: an active oxide layer or a polarized oxide layer.

9. The transistor of claim 7, wherein the first oxide layer and the second oxide layer are a same oxide layer.

10. The transistor of claim 1, wherein the first wide band gap material includes silicon carbide, and wherein the second wide band gap material includes gallium nitride.

11. The transistor of claim 1, wherein the transistor is a part of a wafer scale engine (WSE).

12. A transistor comprising:
a first layer that includes silicon carbide (SiC);
a second layer on the first layer, the second layer includes gallium nitride (GaN);
a gate oxide on a portion of the second layer; and
a gate on the gate oxide.

13. The transistor of claim 12, wherein the gate oxide extends into the second layer.

14. The transistor of claim 12, further comprising:
a first isolation oxide on the second layer;
a second isolation oxide on the second layer, wherein the gate oxide is between the first isolation oxide at the second isolation oxide; and
wherein the first isolation oxide and the second isolation oxide extend into the second layer.

15. The transistor of claim 14, further comprising:
a first region within the second layer and proximate to a top of the second layer, wherein the first region is between the gate oxide and the first isolation oxide; and
a second region within the second layer and proximate to a top of the second layer, wherein the second region is between the gate oxide and the second isolation oxide.

16. The transistor of claim 15, wherein the first region or the second region includes GaN that is p-doped.

17. The transistor of claim 15, wherein the first region or the second region includes a 2D electron gas (2DEG).

18. The transistor of claim 15, further comprising:
a first epitaxial on the first region, wherein the first epitaxial has an n+ doping; and
a second epitaxial on the second region, wherein the second epitaxial has a n+ doping.

19. The transistor of claim 12, further comprising a third layer below the first layer, wherein the third layer includes SiC, wherein the third layer includes n+ doping, and wherein the first layer includes n− doping.

20. The transistor of claim 19, wherein the first layer includes n− doping.

21. The transistor of claim 12, further comprising an electrical contact below the first layer.

22. A method comprising:
providing a first layer that includes silicon carbide (SiC);
providing a second layer on the first layer, wherein the second layer includes gallium nitride (GaN);
forming a cavity through the second layer to expose at least a portion of the first layer, and
placing a gate in the cavity, wherein the gate is above the first layer and between a first portion of the second layer and a second portion of the second layer.

23. The method of claim 22, wherein the first portion of the second layer has a different doping than the second portion of the second layer.

24. The method of claim 22, further comprising:
forming a first oxide layer between the first portion of the second layer and the gate; and
forming a second oxide layer between the second portion of the second layer in the gate, wherein the first oxide layer or the second oxide layer is a selected one or more of: an active oxide layer or a polarized oxide layer.

25. The method of claim 22, further comprising placing an electrical contact below the first layer.
